(19) United States
(12) Patent Application Publication
(10) Pub. No.: US 2025/0044704 A1
(43) Pub. Date: Feb. 6, 2025

(54) SUBSTRATE PROCESSING METHOD, COMPUTER RECORDING MEDIUM, SUBSTRATE PROCESSING SYSTEM, AND SUBSTRATE PROCESSING APPARATUS

(71) Applicant: Tokyo Electron Limited, Tokyo (JP)

(72) Inventors: Yuichi ASAHI, Tokyo (JP); Takuya SEINO, Gyeonggi-do (KR)

(73) Assignee: Tokyo Electron Limited, Tokyo (JP)

(21) Appl. No.: 18/921,159

(22) Filed: Oct. 21, 2024

Related U.S. Application Data
(63) Continuation of application No. PCT/JP2023/015376, filed on Apr. 17, 2023.

(30) Foreign Application Priority Data
Apr. 28, 2022 (JP) 2022-074695

(51) Int. Cl. G03F 7/00; G03F 7/16; G03F 7/20; H01L 21/67

(52) U.S. Cl. CPC G03F 7/70141; G03F 7/162; G03F 7/2002; G03F 7/70025; G03F 7/70525; H01L 21/67063; H01L 21/67253

(57) ABSTRACT

A substrate processing method includes: (A) applying a resist liquid on a substrate to form a resist film, (B) performing auxiliary exposure processing of irradiating the resist film with light having a desired wavelength, separately from exposure processing of transferring a pattern of a mask onto the resist film, (C) supplying a developer to the resist film after the exposure processing and the auxiliary exposure processing to form a resist pattern, (D) etching an etching target layer on the substrate using the resist pattern as a mask, and (E) correcting an in-plane distribution of an exposure amount in the auxiliary exposure processing in (B), and performing the correction based on a result of (D) when (A) to (D) are performed under conditions before the correction.

### CROSS-REFERENCE TO RELATED APPLICATIONS

This application is a bypass continuation application of international application No. PCT/JP2023/015376 having an international filing date of Apr. 17, 2023 and designating the United States, the international application being based upon and claiming the benefit of priority from Japanese Patent Application No. 2022-074695, filed on Apr. 28, 2022, the entire contents of each are incorporated herein by reference.

### TECHNICAL FIELD

The present disclosure relates to a substrate processing method, a computer recording medium, a substrate processing system, and a substrate processing apparatus.

### BACKGROUND

PTL 1 discloses, separately from exposure processing of transferring a pattern of a mask to a resist film applied on a substrate, an auxiliary exposure apparatus for irradiating the resist film on the substrate with light having a desired wavelength.

### CITATION LIST

### Patent Documents

Patent Document 1: JP2018-60001A

### SUMMARY

The technique according to the present disclosure improves uniformity within a substrate surface as an etching result using a resist pattern as a mask.

According to an aspect of the present disclosure, there is provided a substrate processing method that includes: (A) applying a resist liquid on a substrate to form a resist film, (B) performing auxiliary exposure processing of irradiating the resist film with light having a desired wavelength, separately from exposure processing of transferring a pattern of a mask onto the resist film, (C) supplying a developer to the resist film after the exposure processing and the auxiliary exposure processing to form a resist pattern, (D) etching an etching target layer on the substrate using the resist pattern as a mask, and (E) correcting an in-plane distribution of an exposure amount in the auxiliary exposure processing in (B), and performing the correction based on a result of (D) when (A) to (D) are performed under conditions before the correction.

According to the present disclosure, it is possible to improve the uniformity within the substrate surface as the etching result using the resist pattern as the mask.

### BRIEF DESCRIPTION OF DRAWINGS

FIG. 1 is a block diagram showing a schematic processing system as a substrate processing system according to the present embodiment;

FIG. 2 is a block diagram showing a schematic configuration of a control device in FIG. 1;

FIG. 3 is a diagram showing a schematic internal configuration of a coating and developing apparatus in FIG. 1;

FIG. 4 is a diagram showing a schematic internal configuration of a front surface side of the coating and developing apparatus;

FIG. 5 is a diagram showing a schematic internal configuration of a back surface side of the coating and developing apparatus;

FIG. 6 is a cross-sectional view showing a schematic configuration of an auxiliary exposure unit;

FIG. 7 is a vertical sectional view showing a schematic configuration of the auxiliary exposure unit;

FIG. 8 is a plan view showing a schematic configuration of an etching apparatus in FIG. 1;

FIG. 9 is a plan view showing a schematic configuration of a measurement apparatus in FIG. 1;

FIG. 10 is a flowchart for showing an example of processing of a wafer by a processing system in FIG. 1;

FIG. 11 is a flowchart for showing an example of a correction step;

FIG. 12 is a diagram showing an example of correction in the correction step;

FIG. 13 is a diagram showing an example of correction in the correction step;

FIG. 14 is a diagram showing an example of correction in the correction step;

FIG. 15 is a block diagram showing a schematic configuration of a control device provided in a processing system that is a substrate processing system according to a second embodiment;

FIG. 16 is a flowchart for showing an example of processing of a wafer W by the processing system according to the second embodiment;

FIG. 17 is a flowchart for showing an example of a correction step;

FIG. 18 is a flowchart for showing an example of processing of the wafer W by a processing system according to a third embodiment;

FIG. 19 is a flowchart for showing an example of processing of the wafer W by the processing system according to the third embodiment; and

FIG. 20 is a flowchart for showing an example of processing of the wafer W by a processing system according to a fourth embodiment.

### DETAILED DESCRIPTION

In photolithography in a manufacturing process of a semiconductor device or the like, resist coating processing of forming a resist film by applying a resist liquid on a substrate such as a semiconductor wafer (hereinafter, referred to as a wafer), exposure processing of exposing a pattern of a mask to the resist film, and development processing of forming a resist pattern by supplying a developer to the exposed resist film are successively performed. Accordingly, a resist film having a desired pattern, that is, a resist pattern, is formed on the substrate. The above-described exposure is performed, for example, by scanning an area of 35 mm×25 mm on the substrate with an elongated beam formed by a light source and a slit of N mm×25 mm (N is, for example, 1 to 3).

In the manufacturing process of the semiconductor device or the like, etching of an etching target layer on the substrate is performed using the resist pattern formed as described above as a mask.

In the exposure using the slit described above, an exposure amount for each exposure shot is, for example, the same. Here, an exposure shot refers to an area that is irradiated by a single exposure through the slit when scanning is performed using the slit described above and when exposing an entire desired area on the substrate by a plurality of exposures through the slit. The exposure shot is set to partially overlap with another exposure shot adjacent to each other in a scanning direction.

In order to make a line width of the resist pattern uniform within a substrate surface, a method of adjusting the exposure amount for each exposure shot may be adopted.

In the above-described method, the exposure amount can be changed in a direction of scanning through the slit. However, there is room for improvement in terms of in-plane uniformity of the line width of the resist pattern, such as difficulty in changing an exposure amount within one exposure shot (particularly, in a longitudinal direction of the slit for exposure).

Based on this background, the following method has been considered as a method of improving the in-plane uniformity of the line width of the resist pattern. That is, in addition to normal exposure processing to transfer a pattern of a mask, auxiliary exposure processing of irradiating a resist film on a substrate with light having a desired wavelength is performed, for example, a distribution of a total exposure amount in the normal exposure processing and the auxiliary exposure processing is made to have a desired distribution, and a line width of a resist pattern after development processing is made uniform within a substrate surface (see PTLs 1 to 3).

However, an aspect of the etching using a resist mask as a pattern (specifically, an etching rate or the like) varies within the substrate surface. Therefore, even when the line width of the resist pattern after the development processing is uniform within the substrate surface, a line width of the pattern obtained by the etching using the resist pattern as a mask may be non-uniform within the substrate surface.

Therefore, in the technique according to the present disclosure, uniformity within a substrate surface as an etching result using a resist pattern as a mask is improved by auxiliary exposure processing.

Hereinafter, a substrate processing method and a substrate processing system according to the present embodiment will be described with reference to the drawings. Like reference numerals will be given to like parts having substantially the same functions throughout the specification and the drawings, and redundant description thereof will be omitted.

### <Substrate Processing System>

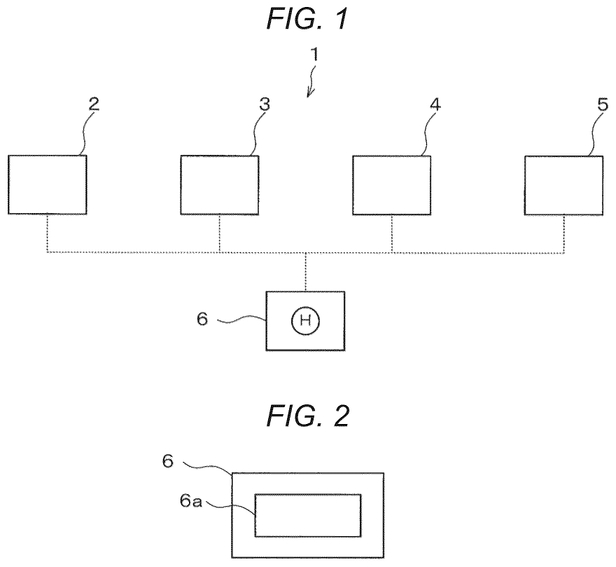

FIG. 1 is a block diagram showing a schematic processing system as a substrate processing system according to the present embodiment. FIG. 2 is a block diagram showing a schematic configuration of a control device 6 (i.e., circuitry) to be described later.

As shown in FIG. 1, a processing system 1 includes a coating and developing apparatus 2 serving as a substrate processing apparatus, an etching apparatus 3, a measurement apparatus 4, a cassette transfer device 5, and the control device 6.

The coating and developing apparatus 2 applies a resist liquid onto a wafer to form a resist film, performs auxiliary exposure processing on the resist film separately from exposure processing, or supplies a developer to the resist film after the exposure processing and the auxiliary exposure processing to form a resist pattern.

The etching apparatus 3 etches the wafer.

The measurement apparatus 4 measures a result of the etching by the etching apparatus 3. The result of the etching is specifically a dimension of a pattern of an etching target layer formed by the etching, and more specifically, for example, a line width of a line-and-space pattern of the etching target layer formed by the etching. The dimension may be a diameter of a hole in a hole pattern of the etching target layer formed by etching.

The cassette transfer device 5 transfers the wafer in cassette units serving as accommodation containers that accommodate a plurality of (for example, 25) wafers. The cassette transfer device 5 transfers the wafer from the coating and developing apparatus 2 to the etching apparatus 3 and transfers the wafer W from the etching apparatus 3 to the measurement apparatus 4 in cassette units.

The control device 6 is, for example, a computer provided with a processor such as a CPU, a memory, and the like, and has a program storage unit (not shown). The program storage unit stores, for example, a program that includes instructions for correcting a distribution of exposure amounts in the auxiliary exposure processing, and a program that includes instructions for controlling processing of the wafer by the processing system 1. The program may be recorded in a recording medium H readable by the computer and may be installed in the control device 6 from the recording medium H. The recording medium H may be temporary or non-temporary medium.

As shown in FIG. 2, the control device 6 includes a correction data storage unit 6a that stores correction data for correcting an exposure condition of the auxiliary exposure processing to be described later.

### Coating and Developing Apparatus 2

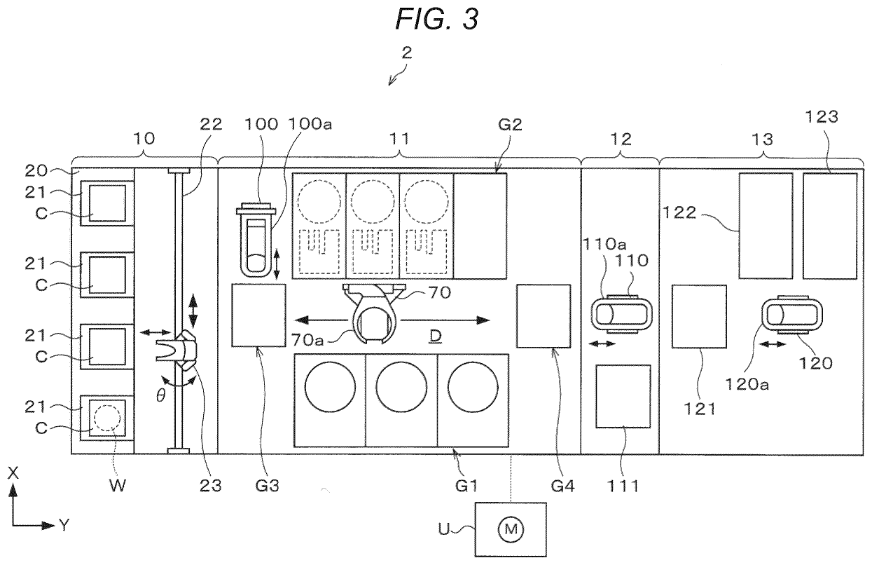

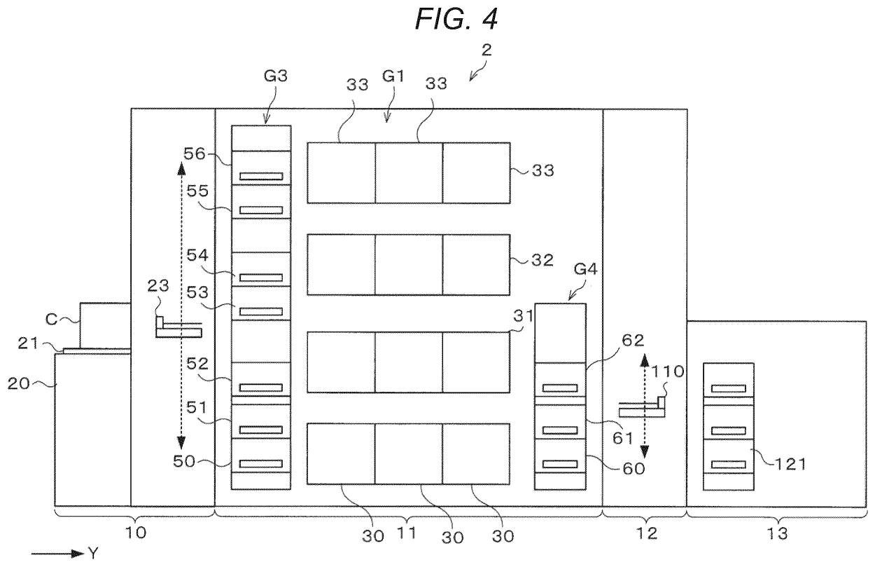

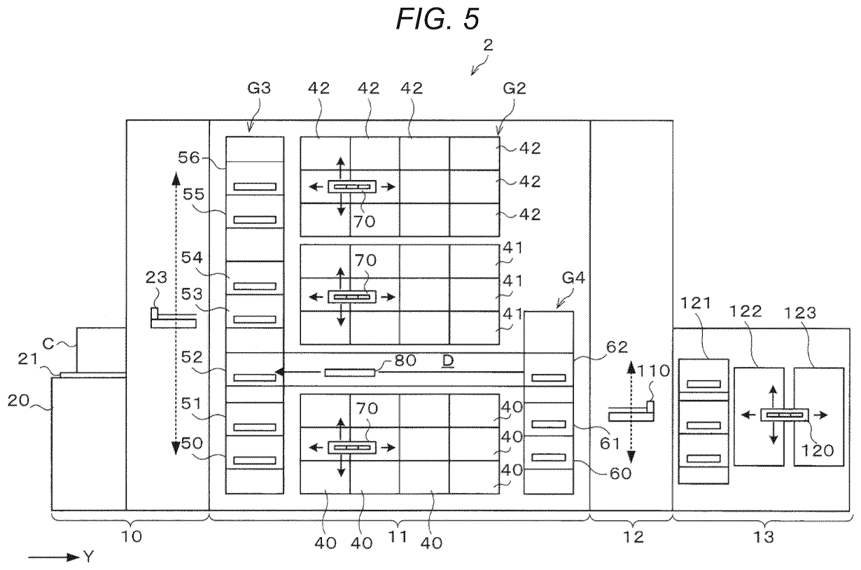

FIG. 3 is a diagram showing a schematic internal configuration of the coating and developing apparatus 2. FIGS. 4 and 5 are diagrams showing a schematic internal configuration of a front surface side and a back surface side of the coating and developing apparatus 2, respectively.

As shown in FIG. 3, the coating and developing apparatus 2 includes a cassette station 10 into and from which a cassette C accommodating a plurality of wafers W is loaded and unloaded, and a processing station 11 provided with a plurality of processing units that perform desired processing on the wafer W one by one. The coating and developing apparatus 2 has an interface station 12 that is disposed adjacent to the processing station 11 in a Y-direction positive direction and that transfers the wafer W to and from an exposure station 13 one by one. The cassette station 10, the processing station 11, and the interface station 12 are integrally connected to each other. Further, the coating and developing apparatus 2 also has an auxiliary exposure unit 123 (i.e., auxiliary exposurer) to be described later in the exposure station 13.

The cassette station 10 includes a cassette placement plate 21 on which the cassette C is mounted, a plurality of cassette placement plates 21 being disposed on a cassette stage 20 along an X direction, and a wafer transfer unit 23 that is movable on a transfer path 22 extending in the X direction. The wafer transfer unit 23 is also movable in an upper-lower direction and around a vertical axis (θ direction), and can transfer the wafer W one by one between the cassette C on each cassette placement plate 21 and a transfer unit of a third block G3 in the processing station 11 to be described later.

The processing station 11 includes a plurality of, for example, four blocks G1, G2, G3, and G4 each having various apparatuses.

As shown in FIG. 4, a plurality of liquid processing units, for example, a developing unit 30, an antireflection film forming unit 31, a resist coating unit 32 (i.e., resist coating applier), and an antireflection film forming unit 33 are disposed in this order from a bottom in the first block G1. The antireflection film forming unit 31 applies a desired processing liquid on the wafer W, and forms an antireflection film (hereinafter, referred to as a lower antireflection film) as a lower layer film at a position that is to be a lower layer of a resist film. The resist coating unit 32 applies a resist liquid onto the wafer W to form a resist film. The antireflection film forming unit 33 applies a desired processing liquid onto the wafer W, and forms an antireflection film (hereinafter, referred to as an upper antireflection film) on an upper layer of the resist film. The developing unit 30 supplies a developer to the resist film after exposure processing and auxiliary exposure processing to form a resist pattern.

In the developing unit 30 (i.e., developer), the antireflection film forming unit 31, the resist coating unit 32, and the antireflection film forming unit 33, a desired processing liquid is applied on the wafer W by, for example, spin coating. In the spin coating, for example, the processing liquid is discharged from a discharge nozzle onto the wafer W, and the wafer W is rotated to diffuse the processing liquid onto a surface of the wafer W.

For example, as shown in FIG. 5, the second block G2 includes a thermal treatment unit 40 that performs thermal treatment such as heating or cooling the wafer W, an adhesion unit 41 for improving adhesion between the resist film and the wafer W, and a peripheral exposure unit 42 that exposes an outer peripheral portion of the wafer W, arranged side by side in the upper-lower direction and in a horizontal direction.

For example, in the third block G3, transfer units 50, 51, 52, 53, 54, 55, and 56 are provided sequentially from the bottom. In the fourth block G4, transfer units 60, 61, and 62 are provided sequentially from the bottom.

As shown in FIG. 3, a wafer transfer area D is formed in an area surrounded by the first to fourth blocks G1 to G4. For example, a wafer transfer unit 70 is disposed in the wafer transfer area D. The wafer transfer unit 70 has, for example, a transfer arm 70a that is movable in a Y direction, a front-rear direction, a θ direction, and the upper-lower direction. The wafer transfer unit 70 can move in the wafer transfer area D and transfer the wafer W to a desired unit in the surrounding first block G1, second block G2, third block G3, and fourth block G4. For example, as shown in FIG. 5, a plurality of wafer transfer units 70 are disposed vertically, and can transfer the wafer W to a desired unit at approximately the same height in each of the blocks G1 to G4, for example.

A shuttle transfer unit 80 that linearly transfers the wafer W between the third block G3 and the fourth block G4 is provided in the wafer transfer area D.

The shuttle transfer unit 80 is linearly movable in the Y direction in FIG. 5, for example. The shuttle transfer unit 80 can move in the Y direction while supporting the wafer W, and transfer the wafer W between the transfer unit 52 in the third block G3 and the transfer unit 62 in the fourth block G4.

As shown in FIG. 3, a wafer transfer unit 100 is provided on an X-direction positive direction of the third block G3. The wafer transfer unit 100 has, for example, a transfer arm 100a that is movable in the front-rear direction, the θ direction, and the upper-lower direction. The wafer transfer unit 100 can move up and down while supporting the wafer W, and can transfer the wafer W to each transfer unit in the third block G3.

The interface station 12 includes a wafer transfer unit 110 and a transfer unit 111. The wafer transfer unit 110 has, for example, a transfer arm 110a that is movable in the Y direction, the θ direction, and the upper-lower direction. The wafer transfer unit 110 can support the wafer W on, for example, a transfer arm, and can transfer the wafer W between each transfer unit in the fourth block G4, the transfer unit 111, and the transfer unit 121 in the exposure station 13.

The exposure station 13 includes a wafer transfer unit 120, a transfer unit 121, an exposure apparatus 122, and the auxiliary exposure unit 123. The wafer transfer unit 120 has, for example, a transfer arm that is movable in the X direction, the Y direction, the θ direction, and the upper-lower direction. For example, the wafer transfer unit 120 can support the wafer W by the transfer arm 120a and transfer the wafer W between the transfer unit 121, the exposure apparatus 122, and the auxiliary exposure unit 123.

The exposure apparatus 122 performs normal exposure processing (hereinafter referred to as “main exposure processing”) for transferring a pattern of a reticle serving as a mask to a resist film on the wafer W.

The auxiliary exposure unit 123 performs auxiliary exposure processing of irradiating a resist film on the wafer W with light having a desired wavelength (for example, ultraviolet light having a wavelength of 267 nm), separately from the main exposure processing by the exposure apparatus 122.

The coating and developing apparatus 2 described above includes a controller U. The controller U is, for example, a computer provided with a processor such as a CPU, a memory, and the like, and has a program storage unit (not shown). The program storage unit stores, for example, a program that includes instructions for controlling processing of the wafer W by the coating and developing apparatus 2 that includes auxiliary exposure processing. The program may be recorded in a recording medium M readable by the computer and may be installed in the controller U from the recording medium M. The recording medium M may be temporary or non-temporary medium.

The controller U may instead have some or all of functions of the control device 6 to be described later, or the control device 6 may instead have some or all of functions of the controller U to be described later.

### Auxiliary Exposure Unit 123

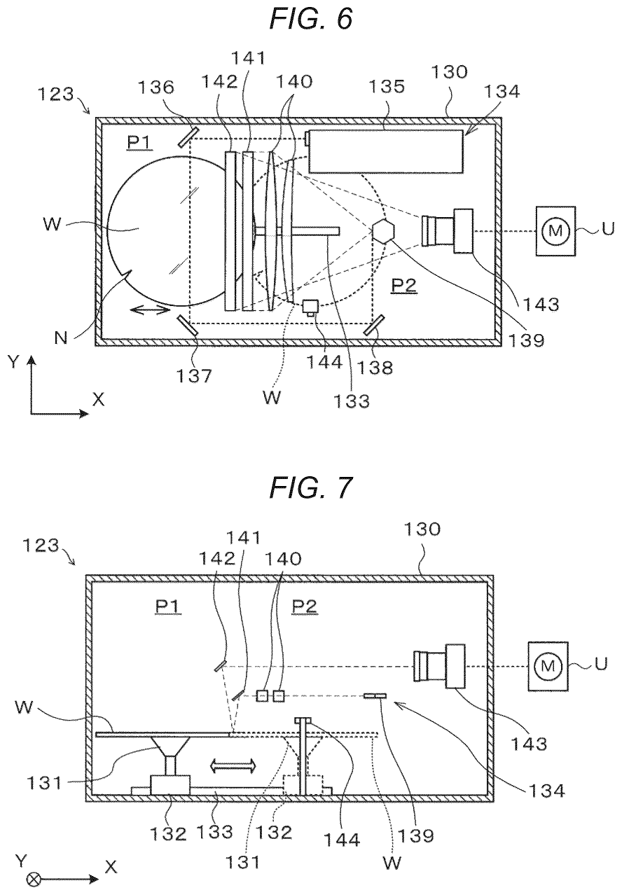

FIGS. 6 and 7 are respectively a cross-sectional view and a vertical sectional view showing a schematic configuration of the auxiliary exposure unit 123, and in FIG. 7, a light source 135 and mirrors 136 to 138 to be described later are omitted.

As shown in FIGS. 6 and 7, the auxiliary exposure unit 123 has a housing 130. A loading and unloading port (not shown) for loading and unloading the wafer W is formed on a side surface of the housing 130. A wafer chuck 131 that attracts and holds the wafer W is provided in the housing 130. The wafer chuck 131 has a horizontal upper surface, and the upper surface is provided with, for example, a suction port (not shown) for suctioning the wafer W. The wafer W can be attracted and held on the wafer chuck 131 by suction from the suction port.

As shown in FIG. 7, the wafer chuck 131 is attached to a chuck driving unit 132. A guide rail 133 extending from one end side (an X-direction negative direction in FIG. 7) to the other end side (the X-direction positive direction in FIG. 7) in the housing 130 is provided on a bottom surface of the housing 130. The chuck driving unit 132 is provided on the guide rail 133.

The chuck driving unit 132 has, for example, a built-in motor (not shown), and is configured to be able to move the wafer chuck 131 freely along the guide rail 133. Accordingly, the wafer W can be moved between a transfer position P1 where the wafer W is transferred to and from an outside of the auxiliary exposure unit 123 and an adjustment position P2 for adjusting an orientation of the wafer W, and the wafer W can be moved in a desired direction (the X direction) during the auxiliary exposure processing. Further, the chuck driving unit 132 can rotate the wafer chuck 131 by, for example, the motor described above.

A scanning exposure module 134 that irradiates the resist film on the wafer W transferred in the X direction (main scanning direction) by the chuck driving unit 132 or the like with light having a desired wavelength is provided in the housing 130. The scanning exposure module 134 irradiates an exposure area provided at a desired pitch on the wafer W with a light beam. Assuming that a unit of the light beam used to irradiate one exposure area is “shot”, the scanning exposure module 134 intermittently performs irradiation with a light beam of one shot, and shifts an irradiation position in the Y direction (direction orthogonal to the main scanning direction) for each shot. That is, the scanning exposure module 134 scans the resist film on the wafer W in the Y direction with a light beam. When a diameter of the wafer W is 300 mm, the exposure area is provided at, for example, a 0.5 mm pitch. A diameter of the light beam emitted by the scanning exposure module 134 is smaller than a diameter of a light beam used for main exposure by the exposure apparatus 122, and is, for example, 1.4 mm.

The scanning exposure module 134 includes the light source 135, the mirrors 136 to 138, a polygon mirror 139, an fθ lens 140, and a first total reflection mirror 141, and the constituent members of the scanning exposure module 134 are located above the wafer W held by the wafer chuck 131.

The light source 135 is a light source that intermittently emits a substantially parallel light beam, specifically, an ultraviolet laser beam, and emits light toward the X-direction negative direction. The light source 135 is disposed at an end portion of the housing 130 in the Y-direction positive direction and at an end portion in the X-direction positive direction.

The mirror 136 reflects light from the light source 135 toward a Y-direction negative direction, and the mirror 137 reflects the light reflected by the mirror 136 toward the X-direction positive direction. The mirror 138 reflects the light reflected by the mirror 137 toward the Y-direction positive direction, that is, toward the polygon mirror 139.

The polygon mirror 139 is a light deflector in which a reflecting surface is disposed in a polygonal shape and can rotate at high speed around a center of the polygon as a rotation axis, and reflects light reflected by the mirror 138 toward the fθ lens 140 successively at different angles. A drive unit (not shown) that includes a motor or the like is provided for the polygon mirror 139, and the polygon mirror 139 is rotated at a desired speed by the drive unit.

The fθ lens 140 changes a traveling direction of the light after passing through the fθ lens 140 from that before entering the fθ lens 140, and changes a traveling direction of the light reflected by the polygon mirror 139 to a desired direction (Y-direction negative direction).

The first total reflection mirror 141 reflects the light reflected by the polygon mirror 139 successively at different angles and passes through the fθ lens 140 toward the surface of the wafer W held by the wafer chuck 131, and enables the wafer W to be scanned in the Y direction using the light reflected by the polygon mirror 139.

The first total reflection mirror 141 is provided such that the light reflected by the mirror 141 is incident on the wafer W at an angle that is not perpendicular to the wafer W. A dimension of the first total reflection mirror 141 in the Y direction is the same as or slightly larger than the diameter of the wafer W, and a dimension in the X direction is sized such that the light reflected by the mirror 141 and reflected by the wafer W does not enter the mirror 141.

Further, a second total reflection mirror 142 and an imaging device 143 are provided above the scanning exposure module 134 inside the housing 130.

The second total reflection mirror 142 reflects light reflected by the first total reflection mirror 141 and then reflected by the wafer W toward the X-direction positive direction, that is, toward the imaging device 143.

The imaging device 143 receives light reflected by the second total reflection mirror 142 and images an exposure state of the wafer W.

A position detection sensor 144 is provided at a position corresponding to the adjustment position P2 inside the housing 130. The position detection sensor 144 includes, for example, a CCD camera (not shown) and detects an amount of eccentricity of the wafer W held by the wafer chuck 131 at the adjustment position P2 from a center, and a position of a notch N of the wafer W. In the auxiliary exposure unit 123, the wafer chuck 131 can be rotated by the chuck driving unit 132 to adjust the orientation of the wafer W, while the position detection sensor 144 detects the position of the notch N.

Among the components described above of the auxiliary exposure unit 123, operations of the chuck driving unit 132, the light source 135, the drive unit of the polygon mirror 139, the imaging device 143, and the like are controlled by the controller U.

### Etching Apparatus 3

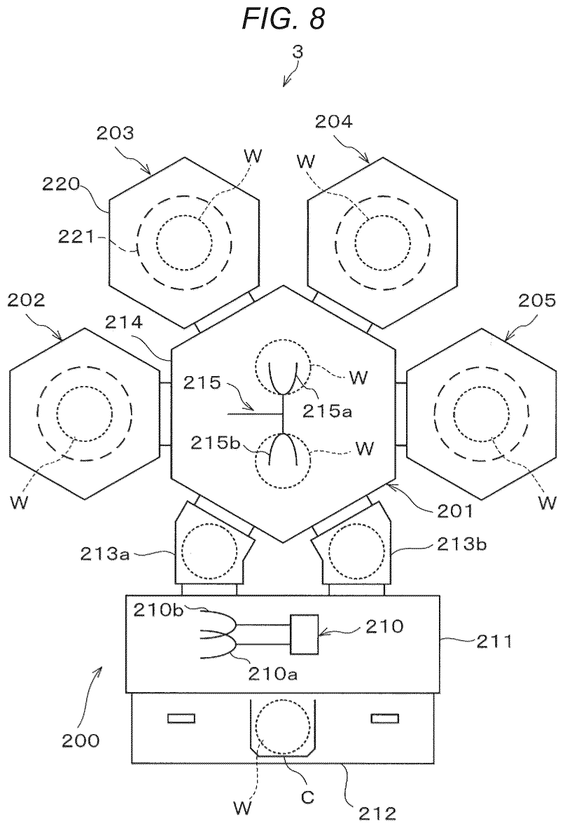

FIG. 8 is a plan view showing a schematic configuration of the etching apparatus 3.

As shown in FIG. 8, the etching apparatus 3 includes a cassette station 200 into and from which the cassette C that accommodates the wafer W is loaded and unloaded, a common transfer unit 201 for transferring the wafer W, and a plurality of (four in the example shown) etching units 202 to 205 (i.e., etchers) that etch an etching target layer on the wafer W using a resist pattern as a mask.

The cassette station 200 has a transfer chamber 211 in which a wafer transfer unit 210 for transferring the wafer W is provided. The wafer transfer unit 210 has two transfer arms 210a and 210b that hold the wafer W substantially horizontally, and is configured to transfer the wafer W while holding the wafer W by either of the transfer arms 210a and 210b. A plurality of cassette stages 212 on which the cassettes C are placed are provided, for example, on a side of the transfer chamber 211.

The transfer chamber 211 and the common transfer unit 201 are connected to each other through two load-lock devices 213a and 213b that can be vacuumed.

The common transfer unit 201 has, for example, a transfer chamber 214 having a sealable structure formed in a substantially polygonal shape (in the shown example, a hexagonal shape) when viewed from above. A wafer transfer unit 215 that transfers the wafer W is provided in the transfer chamber 214. The wafer transfer unit 215 has two transfer arms 215a and 215b that hold the wafer W substantially horizontally, and is configured to transfer the wafer W while holding the wafer W by either of the transfer arms 215a and 215b.

Outside the transfer chamber 214, the etching units 202 to 205 and the load-lock devices 213b and 213a surround a periphery of the transfer chamber 214.

The etching units 202 to 205 perform etching using, for example, plasma of a processing gas. The etching units 202 to 205 form plasma using, for example, parallel plate electrodes.

Each of the etching units 202 to 205 has, for example, a chamber 220 configured to accommodate the wafer W and capable of being depressurized, and a stage 221 or the like provided in the chamber 220 on which the wafer W is placed.

### Measurement Apparatus 4

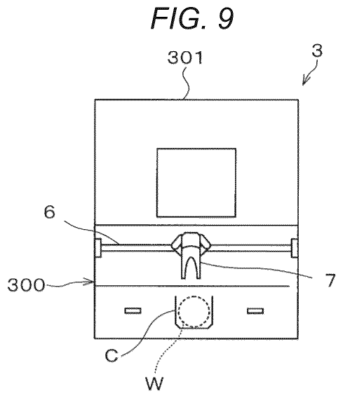

FIG. 9 is a plan view showing a schematic configuration of the measurement apparatus 4.

As shown in FIG. 9, the measurement apparatus 4 includes a cassette station 300 into and from which the cassette C accommodating the wafer W is loaded and unloaded, and a measurement station 301 provided with a measurement unit 320 to be described later.

The cassette station 300 includes a cassette stage 310 on which the cassette C is placed, and a wafer transfer unit 312 that is movable on a transfer path 311. The wafer transfer unit 312 can transfer the wafer W between the cassette C on the cassette stage 310 and the measurement unit 320 in the measurement station 301 one by one.

The measurement unit 320 can measure a dimension of a pattern in each of the areas within the surface of the wafer W. Specifically, with respect to a pattern of an etching target layer formed by the etching apparatus 3, the measurement unit 320 can measure a dimension (more specifically, a line width) of a pattern in each of the areas within the surface of the wafer W.

The measurement unit 320 is, for example, a scanning electron microscope (SEM) unit, but maybe any other known line width measurement unit.

### Wafer Processing

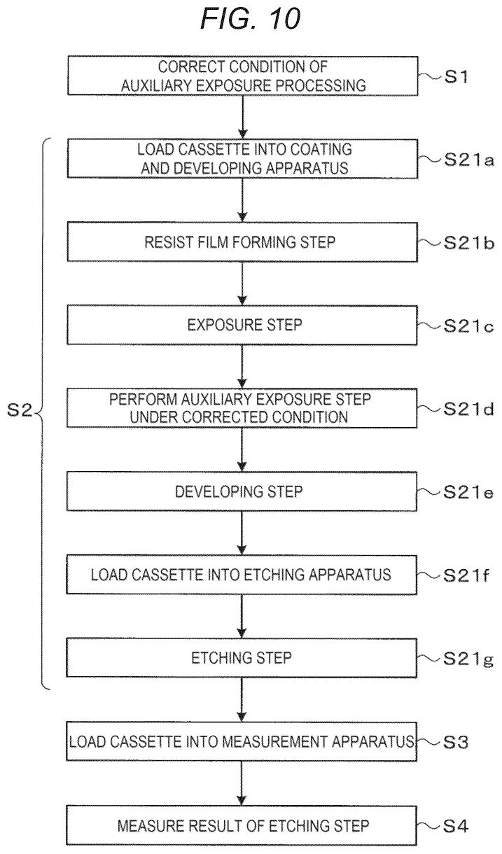

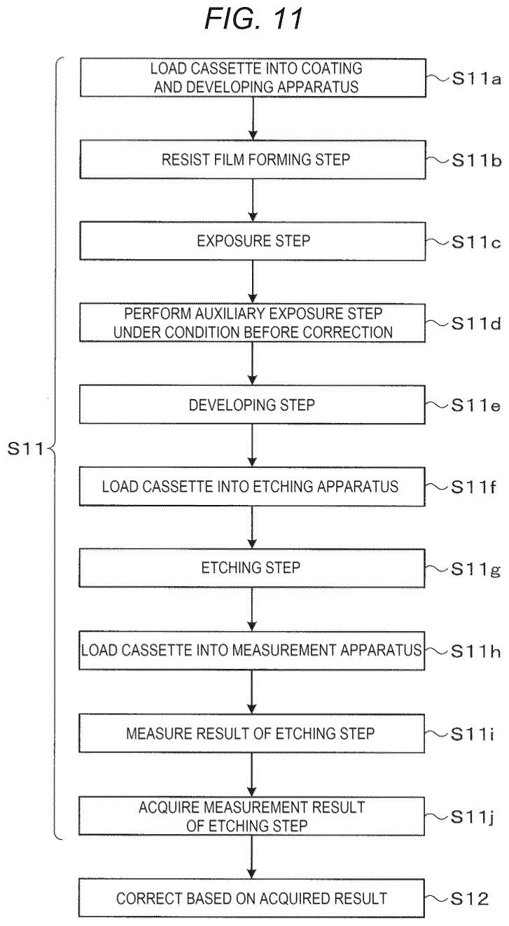

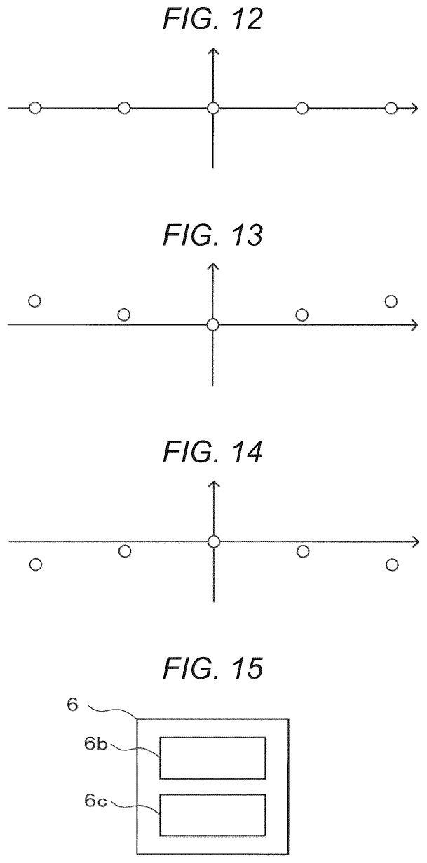

An example of processing of the wafer W by the processing system 1 will be described. FIG. 10 is a flowchart for showing an example of the processing of the wafer W by the processing system 1. FIG. 11 is a flowchart for showing an example of a correction step in step S1 to be described later. FIGS. 12 to 14 are drawings showing examples of correction in the correction step, FIGS. 12 and 13 show examples of a distribution of line widths of a pattern of an etching target layer within the surface of the wafer W, and FIG. 14 shows an example of a distribution of line widths of a resist pattern after development within the surface of the wafer W. In FIGS. 12 to 14, a horizontal axis represents a distance from the center of the wafer W, and a vertical axis represents an error with respect to a target line width.

### [Step S1]

In the processing of the wafer W by the processing system 1, first, as shown in FIG. 10, the control device 6 corrects a condition for the auxiliary exposure processing, that is, corrects a distribution of exposure amounts within the surface of the wafer W. Specifically, the control device 6 performs the correction based on a result of the etching step when a resist film forming step, an auxiliary exposure step, a developing step, and an etching step (hereinafter, referred to as a series of steps) to be described later are performed under conditions before the correction. A result of the etching step is, for example, a distribution of dimensions (specifically, line widths) of a pattern of the etching target layer formed by etching within the surface of the wafer W. Hereinafter, “in-plane” means within the surface of the wafer W.

The correction is performed, for example, when starting up the entire processing system 1 including starting up the etching apparatus 3, or when performing maintenance on the etching apparatus 3.

### [Step S11]

In step S11, for example, as shown in FIG. 11, the control device 6 first acquires a result of the etching step when a series of steps are actually performed under the conditions before the correction.

### (Step S11a)

Specifically, the control device 6 controls the cassette transfer device 5 to load the cassette C that accommodates the wafers W into the cassette station 10 of the coating and developing apparatus 2.

### (Step S11b)

Next, the control device 6 executes control so as to perform a resist film forming step in which a resist liquid is applied onto the wafer W to form a resist film under a desired processing condition.

In the resist film forming step, for example, the wafer W in the cassette C is transferred into the thermal treatment unit 40 in the second block G2 and subjected to temperature adjustment processing, under control of the control device 6 and the controller U. Thereafter, the wafer W is transferred to the antireflection film forming unit 31 in the first block G1, and a lower antireflection film is formed on the wafer W. Subsequently, the wafer W is transferred into the thermal treatment unit 40 in the second block G2, subjected to heating treatment, and subjected to temperature control.

Next, the wafer W is transferred to the adhesion unit 41 and subjected to adhesion processing. Thereafter, the wafer W is transferred to the resist coating unit 32 in the first block G1. Then, a resist liquid is applied onto the wafer W by the resist coating unit 32, and a resist film is formed on the lower antireflection film of the wafer W.

Subsequently, the wafer W is transferred to the antireflection film forming unit 33, and an upper antireflection film is formed on the wafer W. Thereafter, the wafer W is transferred into the thermal treatment unit 40 in the second block G2 and subjected to heating treatment. Next, the wafer W is transferred to the peripheral exposure unit 42 by the wafer transfer unit 70 and subjected to peripheral exposure processing.

### Step S11c

Next, the control device 6 executes controls so as to perform an exposure step in which the main exposure processing is performed under a desired processing condition.

In the exposure step, for example, the wafer W after peripheral exposure is transferred from the peripheral exposure unit 42 to the transfer unit 62 in the fourth block G4, under control of the control device 6 and the controller U. Thereafter, the wafer W is transferred to the exposure station 13 by the wafer transfer unit 110 in the interface station 12.

The wafer W transferred into the exposure station 13 is transferred to the exposure apparatus 122 by the wafer transfer unit 120 in the exposure station 13. Then, normal exposure (main exposure) is performed on the resist film on the wafer W by the exposure apparatus 122.

### Step S11d

Next, the control device 6 executes control so as to perform an auxiliary exposure step in which auxiliary exposure processing is performed under a condition before the correction.

In the auxiliary exposure step, for example, the wafer W after the main exposure is transferred to the auxiliary exposure unit 123, under control of the control device 6 and the controller U. Then, the auxiliary exposure unit 123 performs auxiliary exposure on the resist film on the wafer W.

In the auxiliary exposure unit 123, first, the wafer W is placed on the wafer chuck 131 located at the transfer position P1 and attracted and held. Thereafter, the wafer chuck 131 is moved to the adjustment position P2. Next, the wafer chuck 131 is rotated, and a position of the notch N of the wafer W held by the wafer chuck 131 is detected by the position detection sensor 144. Subsequently, the wafer chuck 131 is rotated again, and the position of the notch N of the wafer W held by the wafer chuck 131 is shifted by a desired angle from an extending direction of the guide rail 133. The wafer chuck 131 is moved to a start position of the auxiliary exposure with respect to the X direction.

Thereafter, the wafer W is scanned with light from the light source 135. That is, auxiliary exposure is performed. Specifically, the light source 135 is driven based on given exposure data before correction, and as the polygon mirror 139 rotates, light emitted from the light source 135 is reflected by the polygon mirror 139 and then reflected by the first total reflection mirror 141, and the wafer W is scanned in the Y direction by the light. As the wafer chuck 131 holding the wafer W is moved in the X direction, the wafer W is scanned in the X direction with light emitted from the light source 135, reflected by the polygon mirror 139, and reflected by the first total reflection mirror 141.

Exposure data for driving the light source 135 is, for example, data of illuminance for each exposure area on the wafer W.

The desired exposure data before correction used in the auxiliary exposure is, for example, data that makes a line width of a resist pattern obtained after development in step S11e to be described later uniform within the surface, and is stored in advance in a storage unit (not shown) of the controller U.

When the auxiliary exposure is completed, the wafer chuck 131 holding the wafer W is moved to the transfer position P1. In order to send out the wafer W from the auxiliary exposure unit 123 at a designated angle, the wafer chuck 131 holding the wafer W is rotated by a desired angle.

Here, the auxiliary exposure is performed after the main exposure, but the auxiliary exposure may be performed before the main exposure.

### Step S11e

Next, the control device 6 executes control so as to perform a developing step of supplying a developer to the resist film after the exposure processing and the auxiliary exposure processing to form a resist pattern under a desired condition.

In the developing step, for example, the wafer W after the main exposure and the auxiliary exposure is transferred from the exposure station 13 to the transfer unit 60 in the fourth block G4, under control of the control device 6 and the controller U. Thereafter, the wafer W is transferred to the thermal treatment unit 40 and subjected to a post-exposure baking processing. Next, the wafer W is transferred to the developing unit 30. Then, the wafer W is developed by the developing unit 30. That is, the developer is supplied onto the resist film on the wafer W by the developing unit 30, so that a resist pattern is formed. Next, the wafer W is transferred to the thermal treatment unit 40 and subjected to post-baking processing. Thereafter, the wafer W is transferred to the cassette C in the cassette station 10.

Steps S11b to S11e described above are performed on, for example, all of the wafers W in the cassette C.

### Step S11f

Next, the control device 6 controls the cassette transfer device 5 to load the cassette C that accommodates the wafer W on which the resist pattern is formed, into the cassette station 200 of the etching apparatus 3.

### Step S11g

Next, the control device 6 executes control so as to perform an etching step of etching an etching target layer on the wafer W under a desired processing condition using the resist pattern as a mask.

In the etching step, for example, the wafer W in the cassette C is loaded into the transfer chamber 214 via the load-lock device 213a, under the control of the control device 6 and a controller (not shown) of the etching apparatus 3. Next, the wafer W is transferred to any of the etching units 202 to 205. Then, in the etching unit as a transfer destination, etching using the resist pattern as a mask is performed, an etching target layer in a portion exposed from the resist pattern is removed, and a pattern of the etching target layer is formed. Thereafter, the wafer W is transferred to the cassette C in the cassette station 200.

This step S11g is performed, for example, for all of the wafers W in the cassette C. In this case, for example, step S11g is performed such that each of the etching units 202 to 205 is used at least once.

### Step S11h

Subsequently, the control device 6 controls the cassette transfer device 5 to load the cassette C that accommodates the wafer W on which the pattern of the etching target layer is formed, into the cassette station 300 of the measurement apparatus 4.

### Step S11i

Next, the control device 6 executes control so as to perform a step of measuring a result of the etching step in step S11g.

Specifically, the wafer W in the cassette C is transferred to the measurement unit 320 under control of the control device 6 and a controller (not shown) of the measurement apparatus 4. Then, the measurement unit 320 measures a dimension (specifically, a line width) of the pattern of the etching target layer with respect to each of the areas within the surface of the wafer W whose positions in a radial direction around the center of the wafer W are different from each other. That is, the measurement unit 320 measures an in-plane distribution of the dimension of the pattern of the etching target layer. Thereafter, a measurement result is output from the controller to the control device 6.

This step S11i is performed, for example, for all of the wafers W in the cassette C.

### Step S11j

Thereafter, the control device 6 acquires the result of the etching step in step S11g.

Specifically, the control device 6 acquires the in-plane distribution of the dimension of the pattern of the etching target layer measured by the measurement apparatus 4 from the controller of the measurement apparatus 4. The control device 6 calculates an error with respect to a target value of the dimension of the pattern of the etching target layer in each area on wafer W, that is, an in-plane distribution of the error, based on the acquired in-plane distribution.

### [Step S12]

The control device 6 corrects an in-plane distribution of an exposure amount in the auxiliary exposure processing based on the result of the etching step acquired in step S11j when a series of steps are actually performed under the conditions before the correction.

This correction is performed, for example, as follows.

That is, the correction is performed such that the in-plane distribution of the line width of the resist pattern after the development corresponds to the in-plane distribution of the line width of the pattern of the etching target layer acquired in step S11. Specifically, correction is performed such that when a series of steps are performed under corrected conditions, the line width of the pattern of the etching target layer after the etching step becomes uniform within the surface as shown in FIG. 12. For example, when the in-plane distribution of the line width of the pattern of the etching target layer acquired in step S11 is a distribution in which the line width becomes narrower toward an outside of the wafer W as shown in FIG. 13, correction is performed such that the in-plane distribution of the line width of the resist pattern after development becomes a distribution in which the line width becomes wider toward the outside of the wafer W as shown in FIG. 14.

The result of the etching step acquired in step S11i and used for correction is, for example, a statistical value (for example, an average value) among the etching units 202 to 205.

Specifically, “correction” refers to calculation of correction data with respect to the in-plane distribution of the exposure amount in the auxiliary exposure processing. The correction data refers to, for example, data for correcting exposure data for driving the light source 135 of the auxiliary exposure unit 123 during the auxiliary exposure. Specifically, the correction data is an in-plane distribution of a correction value of the exposure amount during the auxiliary exposure, that is, a correction value of illuminance by the light source 135, for each of the areas on the wafer W. The correction value for each area on the wafer W is calculated based on, for example, the error with respect to the target value of the dimension of the pattern of the etching target layer in the corresponding area calculated in step S11j, and the following data. That is, the correction value is data indicating a correspondence between the error and the correction value of the illuminance. The data is acquired in advance and stored in the storage unit (not shown) of the control device 6.

The correction data calculated by the control device 6 is stored in the correction data storage unit 6a.

### [Step S2]

As shown in FIG. 10, when the correction in step S1 is completed, the control device 6 executes control so as to perform a series of steps under the corrected conditions.

### Step S21a

Specifically, similar to step S11a described above, the control device 6 loads the cassette C that accommodates the wafers W into the cassette station 10 of the coating and developing apparatus 2.

### Step S21b

Next, similar to step S11b described above, the control device 6 executes control so as to perform a resist film forming step under a desired processing condition.

The processing condition for step S21b is the same as the processing condition for step S11b described above.

### Step S21c

Next, similar to step S11c described above, the control device 6 executes control so as to perform an exposure step under a desired processing condition.

The processing condition for step S21c is the same as the processing condition for step S11c described above.

### Step S21d

Next, unlike step S11d described above, the control device 6 executes control so as to perform the auxiliary exposure step under the corrected condition.

Step S21d is different from step S11 described above only in terms of the in-plane distribution of the exposure amount in the auxiliary exposure processing. Specifically, step S21d differs from step S11d described above only in exposure data for driving the light source 135 of the auxiliary exposure unit 123 during the auxiliary exposure. In step S11d, uncorrected exposure data is used, and in contrast, in step S21d, corrected exposure data is used.

Therefore, for example, the controller U of the coating and developing apparatus 2 acquires correction data stored in the correction data storage unit 6a of the control device 6 before the auxiliary exposure in step S21d, and generates corrected exposure data based on the correction data and the uncorrected exposure data stored in advance in a storage unit (not shown).

Here, the auxiliary exposure is performed after the main exposure, but the auxiliary exposure may be performed before the main exposure. An order of the main exposure and the auxiliary exposure may be the same in step S1 and step S2.

### Step S21e

Next, similar to step S11e described above, the control device 6 executes control so as to perform a developing step under a desired condition.

The processing condition for step S21e is the same as the processing condition for step S11e described above.

Steps S21b to S21e described above are performed for, for example, all of the wafers W in the cassette C.

### Step S21f

Next, similar to step S11f described above, the control device 6 loads the cassette C that accommodates the wafer W on which the resist pattern is formed into the cassette station 200 of the etching apparatus 3.

### Step S21g

Next, similar to step S11g described above, the control device 6 executes control so as to perform an etching step using the resist pattern as a mask under a desired processing condition.

The processing condition for step S21g is the same as the processing condition for step S11g described above.

### [Step S3]

Subsequently, similar to step S11i described above, the control device 6 may load the cassette C that accommodates the wafer W on which the pattern of the etching target layer is formed, into the cassette station 300 of the measurement apparatus 4.

### [Step S4]

Then, similar to step S11j described above, the control device 6 may execute control so as to perform a step of measuring a result of the etching step in step S21g.

This step S4 may be performed, for example, for all of the wafers W in the cassette C, or for only a portion of the wafers W.

Thereafter, the control device 6 may acquire the result of the etching step in step S21g, and further correct an in-plane distribution of an exposure amount in auxiliary exposure processing after correction, based on the acquired result. That is, the control device 6 may update the correction data related to the auxiliary exposure processing based on the acquired result. The updated correction data is stored in the correction data storage unit 6a and used in subsequent auxiliary exposure in step S11d.

### Main Effect of Present Embodiment

As described above, in the present embodiment, the control device 6 corrects the in-plane distribution of the exposure amount in the auxiliary exposure processing based on the result of the etching step when a series of steps including the resist film forming step, the etching step, and the like are performed under the conditions before the correction. Therefore, the in-plane distribution of the dimension of the resist pattern obtained through the auxiliary exposure processing after the correction can be made to correspond to an in-plane distribution of an etching mode (specifically, an etching rate or the like) in the etching step. Therefore, by performing the etching step using the resist pattern obtained through the auxiliary exposure processing after correction as a mask, in-plane uniformity of the pattern of the etching target layer can be improved. Specifically, when a series of steps are performed under the conditions before the correction, such as when a series of steps are performed under conditions that make the resist pattern uniform within the surface, even if the pattern of the etching target layer formed in the etching step becomes non-uniform in the radial direction within the surface, non-uniformity can be alleviated. Thus, according to the present embodiment, in-plane uniformity of the etching result using the resist pattern as a mask can be improved by the auxiliary exposure processing.

The correction according to the present embodiment is effective when performing etching using plasma in the etching step in the series of steps described above, particularly when performing etching using plasma formed by parallel plate electrodes. This is because in the etching using plasma, in particular, in the etching using plasma formed by the parallel plate electrodes, it is difficult to make the in-plane distribution of the etching mode uniform in the radial direction.

Further, in the present embodiment, the in-plane distribution of the exposure amount in the auxiliary exposure processing is corrected based on the result of the etching step when a series of steps are actually performed under conditions before the correction. That is, in the present embodiment, the correction is performed according to an actual state of the processing system 1. Therefore, according to the present embodiment, it is possible to more reliably improve the in-plane uniformity of an etching result using a resist pattern as a mask.

### Second Embodiment

### Control Device

FIG. 15 is a block diagram showing a schematic configuration of a control device provided in a processing system that is a substrate processing system according to a second embodiment.

A configuration of the processing system according to the present embodiment and a configuration of the processing system 1 according to the first embodiment differ only in a configuration of the control device 6.

In the present embodiment, each wafer W is assigned with a wafer ID as wafer identification information and a unit ID as identification information on the etching unit (any of the etching units 202 to 205) used for etching the wafer W.

As shown in FIG. 15, the control device 6 according to the present embodiment includes a correction data storage unit 6b and a corresponding unit ID storage unit 6c. The correction data storage unit 6b stores correction data for correcting an exposure condition of auxiliary exposure processing for each etching unit, that is, for each unit ID. The corresponding unit ID storage unit 6c stores, for each wafer ID, a unit ID of the etching unit used for etching of the wafer W to which the wafer ID is assigned.

The processing system according to the present embodiment may include a plurality of etching apparatuses 3 each having a plurality of etching units. In this case, for example, the unit ID is set such that the etching apparatus 3 including the etching unit indicated by the unit ID can be identified from the unit ID.

### Wafer Processing

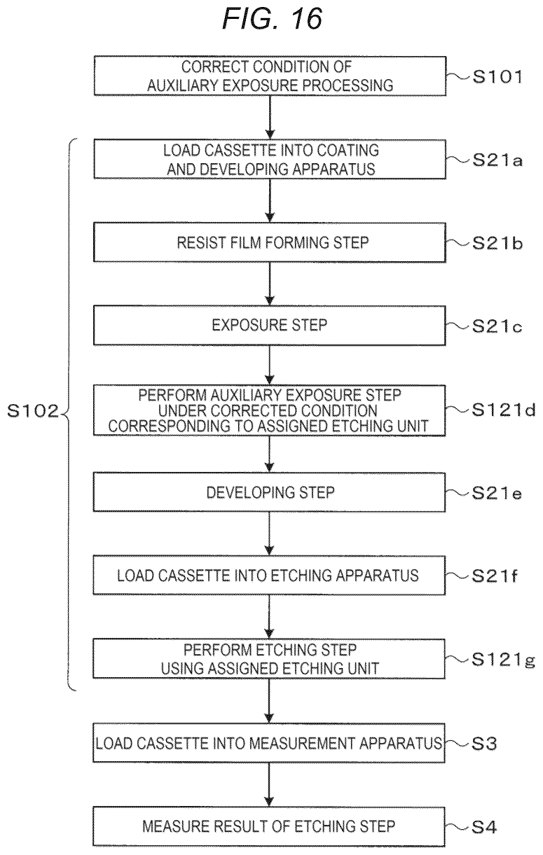

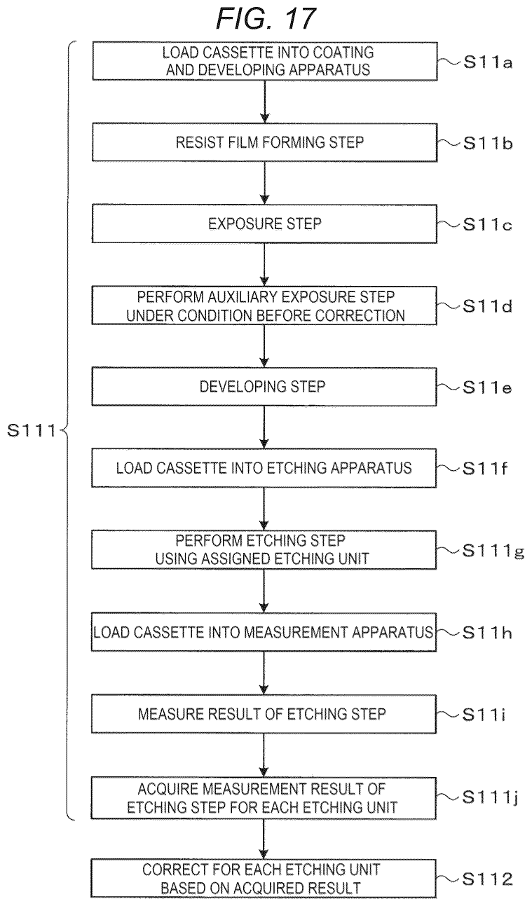

An example of the processing of the wafer W by the processing system according to the present embodiment will be described. FIG. 16 is a flowchart for showing an example of processing of the wafer W by the processing system according to the present embodiment. FIG. 17 is a flowchart for showing an example of a correction step in step S101 to be described later.

### [Step S101]

In the processing of the wafer W by the processing system according to the present embodiment as well, first, as shown in FIG. 16, the control device 6 corrects an in-plane distribution of an exposure amount in the auxiliary exposure processing. Specifically, the control device 6 performs the correction based on a result of an etching step when a series of steps are performed under conditions before the correction.

The correction is performed, for example, when starting up the entire processing system 1 including starting up the etching apparatus 3, or when performing maintenance on the etching apparatus 3.

### [Step S111]

In step S101, for example, as shown in FIG. 17, the control device 6 first acquires a result of the etching step when a series of steps are actually performed under conditions before the correction.

Specifically, first, the above-described steps S11a, S11b, S11c, S11d, and S11e are performed, and a resist pattern is formed on the wafer W in the cassette C.

Subsequently, step S11f described above is performed, and the cassette C that accommodates the wafer W on which the resist pattern is formed is loaded into the cassette station 200 of the etching apparatus 3.

When the processing system according to the present embodiment includes a plurality of etching apparatuses, the cassette C is transferred to the cassette station 200 of the etching apparatus 3 having the etching unit assigned to the wafer W in the cassette C, under control of the control device 6. Specifically, for example, the control device 6 refers to the corresponding unit ID storage unit 6c, extracts a unit ID corresponding to a wafer ID of the wafer W in the cassette C that is a transfer target, and specifies the etching apparatus 3 having the etching unit indicated by the unit ID. Then, the cassette C is transferred to the cassette station 200 of the specified etching apparatus 3 by the cassette transfer device 5 under control of the control device 6.

### Step S111g

Next, the control device 6 executes control so as to perform an etching step under a desired processing condition using a specific etching unit assigned to the wafer W.

In the etching step of step S111g, specifically, the wafer W in the cassette C is transferred to any of the etching units 202 to 205 assigned to the wafer W, under control of the control device 6 and the controller (not shown) of the etching apparatus 3. Then, in the etching unit as a transfer destination, etching is performed using the resist pattern as a mask. In order to make this possible, the control device 6 refers to the corresponding unit ID storage unit 6c in advance, extracts a unit ID corresponding to a wafer ID of the wafer W that is an etching target, and sends the unit ID to the controller of the etching apparatus 3.

This step S111g is performed, for example, for all of the wafers W in the cassette C. A unit ID is assigned to each of the etching units 202 to 205 such that step S111g using the etching unit is performed at least once.

### Step S11h

Subsequently, the above-described steps S11h and S11i are performed, and a result of the etching step in step S111g is measured for each wafer W in the cassette C.

### Step S111j

Thereafter, the control device 6 acquires the result of the etching step in step S1l1g for each etching unit.

Specifically, the control device 6 acquires an in-plane distribution of a dimension of a pattern of an etching target layer measured by the measurement apparatus 4 and a wafer ID for each wafer W from the controller of the measurement apparatus 4. Then, the control device 6 refers to the corresponding unit ID storage unit 6c, and summarizes the in-plane distribution of the dimension of the pattern of the etching target layer measured by the measurement apparatus 4, for each unit ID. The control device 6 calculates, for each unit ID, an error with respect to a target value of the dimension of the pattern of the etching target layer in each area on wafer W, that is, an in-plane distribution of the error, based on the in-plane distribution of the dimension of the etching target layer.

### [Step S112]

The control device 6 corrects an in-plane distribution of an exposure amount in the auxiliary exposure processing for each etching unit based on the result of the etching step acquired in step S111j when a series of steps are actually performed under conditions before the correction.

That is, the control device 6 calculates correction data for the in-plane distribution of the exposure amount in the auxiliary exposure processing for each etching unit. The calculated correction data is stored in the correction data storage unit 6b for each etching unit, that is, for each unit ID.

### [Step S102]

As shown in FIG. 16, when the correction in step S101 is completed, the control device 6 executes control such that a series of steps are performed for each wafer W under corrected conditions corresponding to the etching unit scheduled to be used in a subsequent etching step.

Specifically, the control device 6 performs steps S21a, S21b, and S21c described above, forms a resist film on the wafer W, and performs main exposure.

### Step S121d

Next, the control device 6 executes control so as to perform an auxiliary exposure step under a corrected condition corresponding to the etching unit scheduled to be used in the subsequent etching step, that is, the etching unit assigned to the wafer W that is a processing target.

Step S121d is different from step S11d described above only in terms of an in-plane distribution of an exposure amount in the auxiliary exposure processing. Specifically, step S121d differs from step S11d described above only in exposure data for driving the light source 135 of the auxiliary exposure unit 123 during the auxiliary exposure. In step S11d, uncorrected exposure data is used, and in contrast, in step S121d, the corrected exposure data corresponding to the etching unit assigned to the wafer W that is the processing target is used.

Therefore, for example, the control device 6 refers to the corresponding unit ID storage unit 6c, extracts a unit ID corresponding to a wafer ID assigned to the wafer W that is the processing target, and further refers to the correction data storage unit 6b, extracts correction data corresponding to the extracted unit ID, and sends the correction data to the controller U of the coating and developing apparatus 2. Then, before the auxiliary exposure in step S121d, the controller U of the coating and developing apparatus 2 generates corrected exposure data corresponding to the etching unit assigned to the wafer W that is the processing target, based on the correction data received from the control device 6 and the uncorrected exposure data stored in advance in a storage unit (not shown).

Subsequently, step S21e described above is performed.

Steps S21b, S21c, S121d, and S21e described above are performed for, for example, all of the wafers W in the cassette C.

Next, similar to step S21f described above, the cassette C that accommodates the wafer W on which the resist pattern is formed is loaded into the cassette station 200 of the etching apparatus 3.

When the processing system according to the present embodiment includes the plurality of etching apparatuses 3, the cassette C is transferred to the cassette station 200 of the etching apparatus 3 having the etching unit assigned to the wafer W in the cassette C, under control of the control device 6.

### Step S121g

Next, similar to step S111g described above, the control device 6 executes control so as to perform an etching step under a desired processing condition using the specific etching unit assigned to the wafer W.

The processing condition for step S121g is the same as the processing condition for step S111g described above.

In the present embodiment as well, the above-described steps S3 and S4 may be performed. In the present embodiment as well, the control device 6 may acquire a result of the etching step in step S121g for each etching unit, and further correct the in-plane distribution of the exposure amount in the auxiliary exposure processing after correction for each etching unit based on the acquired result. That is, the control device 6 may update the correction data related to the auxiliary exposure processing based on the acquired result. The updated correction data is stored in the correction data storage unit 6a and used in subsequent auxiliary exposure in step S121d.

### Main Effect of Present Embodiment

According to the present embodiment, the in-plane distribution of the dimension of the resist pattern obtained through the auxiliary exposure processing after correction can be made to correspond to the in-plane distribution of the etching mode (specifically, an etching rate or the like) in the etching unit scheduled to be used in the etching step. Therefore, by performing the etching step using the resist pattern obtained through auxiliary exposure processing after correction as a mask, the in-plane uniformity of the pattern of the etching target layer can be more appropriately improved. That is, according to the present embodiment, improvement of the in-plane uniformity of the etching result using the resist pattern as a mask by the auxiliary exposure processing can be more appropriately performed.

### Third Embodiment

### Control Device

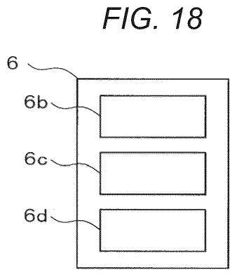

FIG. 18 is a block diagram showing a schematic configuration of a control device provided in a processing system that is a substrate processing system according to a third embodiment.

A configuration of the processing system according to the present embodiment and a configuration of the processing system according to the second embodiment differ only in a configuration of the control device 6.

In the present embodiment, the control device 6 counts the number of wafers W for which an etching step is actually performed using an etching unit, that is, a cumulative number of actually processed wafers W, for each etching unit (specifically, for each unit ID). As shown in FIG. 18, the control device 6 according to the present embodiment further includes a processing count storage unit 6d that stores the number of processed wafers described above for each etching unit (specifically, for each unit ID), in addition to the correction data storage unit 6b and the corresponding unit ID storage unit 6c.

### Wafer Processing

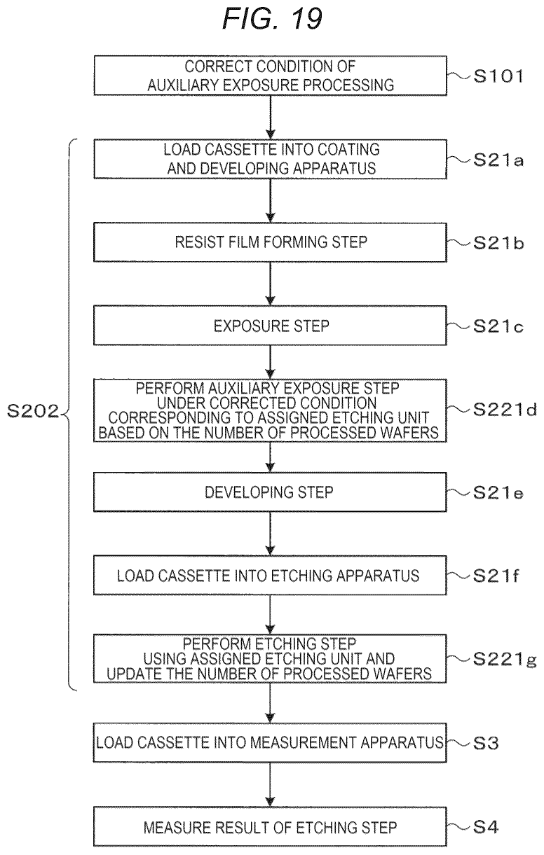

An example of the processing of the wafer W by the processing system according to the present embodiment will be described. FIG. 19 is a flowchart for showing an example of processing of the wafer W by a processing system according to the present embodiment.

In the processing of the wafer W by the processing system according to the present embodiment as well, first, as shown in FIG. 19, the above-described step S101 is performed, and an in-plane distribution of an exposure amount in auxiliary exposure processing is corrected.

### [Step S202]

Thereafter, the control device 6 executes control such that a series of steps are performed for each wafer W under corrected conditions corresponding to an etching unit scheduled to be used in a subsequent etching step.

Specifically, steps S21a, S21b, and S21c described above are performed, a resist film is formed on the wafer W, and main exposure is performed.

### Step S221d

Next, the control device 6 executes control so as to perform an auxiliary exposure step under the corrected condition(s) corresponding to the etching unit scheduled to be used in a subsequent etching step and further corrected based on the number of processed wafers processed by the etching unit.

Step S221d is different from step S121d described above only in terms of an in-plane distribution of an exposure amount in the auxiliary exposure processing. Specifically, step S221d differs from step S121d described above only in exposure data for driving the light source 135 of the auxiliary exposure unit 123 during the auxiliary exposure. In step S121d, the corrected exposure data corresponding to the etching unit assigned to the wafer W that is the processing target is used, while in step S221d, the corrected exposure data is used, which is corrected based on the number of actually processed wafers processed by the etching unit assigned to the wafer W that is the processing target.

Therefore, for example, the control device 6 refers to the corresponding unit ID storage unit 6c, extracts a unit ID corresponding to a wafer ID assigned to the wafer W that is the processing target, and further refers to the correction data storage unit 6b, and extracts correction data corresponding to the extracted unit ID. The control device 6 also refers to the processing count storage unit 6d to extract the number of actually processed wafers corresponding to the extracted unit ID. Further, the control device 6 corrects the extracted correction data based on the extracted number of actually processed wafers.

In other words, in the present embodiment, the control device 6 corrects the in-plane distribution of the exposure amount in the auxiliary exposure processing, based on a measurement result of the etching step when a series of steps including the etching step are actually performed in the past using the etching unit scheduled to be used in the subsequent etching step, and the number of actually processed wafers processed by the etching unit.

The corrected correction data is sent to the controller U of the coating and developing apparatus 2.

Then, before the auxiliary exposure in step S121d, the controller U of the coating and developing apparatus 2 generates corrected exposure data corresponding to the etching unit assigned to the wafer W that is the processing target, based on the correction data corrected based on the number of actually processed wafers received from the control device 6 and the uncorrected exposure data stored in advance in a storage unit (not shown).

Further correction of the correction data based on the number of actually processed wafers described above by the control device 6 is performed using, for example, the following data. That is, the data is data showing a correspondence between the number of actually processed wafers and the in-plane distribution of a correction amount corresponding to an amount of change of the error described above. The data is acquired in advance and stored in the storage unit (not shown) of the control device 6. The data may be different for each etching unit, or maybe the same between etching units. When the data is different for each etching unit, the auxiliary exposure can be more appropriately performed.

Subsequently, step S21e described above is performed.

Steps S21b, S21c, S221d, and S21e described above are performed for, for example, all of the wafers W in the cassette C.

Next, similar to step S21f described above, the cassette C that accommodates the wafer W on which the resist pattern is formed is loaded into the cassette station 200 of the etching apparatus 3.

When the processing system according to the present embodiment includes the plurality of etching apparatuses 3, the cassette C is transferred to the cassette station 200 of the etching apparatus 3 having the etching unit assigned to the wafer W in the cassette C, under control of the control device 6.

### Step S221g

Next, similar to step S121g described above, the control device 6 executes control so as to perform an etching step under a desired processing condition using the specific etching unit assigned to the wafer W.

In step S221g, unlike step S121g described above, the control device 6 also updates information on the number of processed wafers processed by a specific etching unit assigned to the wafer W. Specifically, when the control device 6 extracts a unit ID corresponding to a wafer ID of the etching target wafer W and sends the unit ID to the controller of the etching apparatus 3, the control device 6 counts up the number of processed wafers corresponding to the unit ID stored in the processing count storage unit 6d and stores the number of processed wafers again.

When maintenance of the etching unit is performed, the number of processed wafers processed by the etching unit may be reset to zero.

In the present embodiment as well, the above-described steps S3 and S4 may be performed.

### Main Effect of Present Embodiment

According to the present embodiment, the in-plane distribution of the dimension of the resist pattern obtained through the auxiliary exposure processing after correction can be made to correspond to
an in-plane distribution of an etching mode (specifically, an etching rate or the like) in an etching unit scheduled to be used in the etching step, and
a change over time in an etching mode in an etching unit scheduled to be used in the etching step. Therefore, by performing the etching step using the resist pattern obtained through auxiliary exposure processing after correction as a mask, the in-plane uniformity of the pattern of the etching target layer can be more appropriately improved.

### Fourth Embodiment

### Control Device

A configuration of the processing system according to the present embodiment and a configuration of the processing system according to the third embodiment differ only in a configuration of the control device 6.

In the third embodiment, as described above, the control device 6 corrects the in-plane distribution of the exposure amount in the auxiliary exposure processing, based on a measurement result of the etching step when a series of steps including the etching step are actually performed in the past using the etching unit scheduled to be used in the subsequent etching step, and the number of actually processed wafers processed by the etching unit.

In contrast, in the present embodiment, the control device 6 acquires a predicted result of the etching step when performing the series of steps using an etching unit scheduled to be used in a subsequent etching step, based on the number of actually processed wafers processed by the etching unit, and corrects the in-plane distribution of the exposure amount in the auxiliary exposure processing, based on the acquired result.

### Wafer Processing

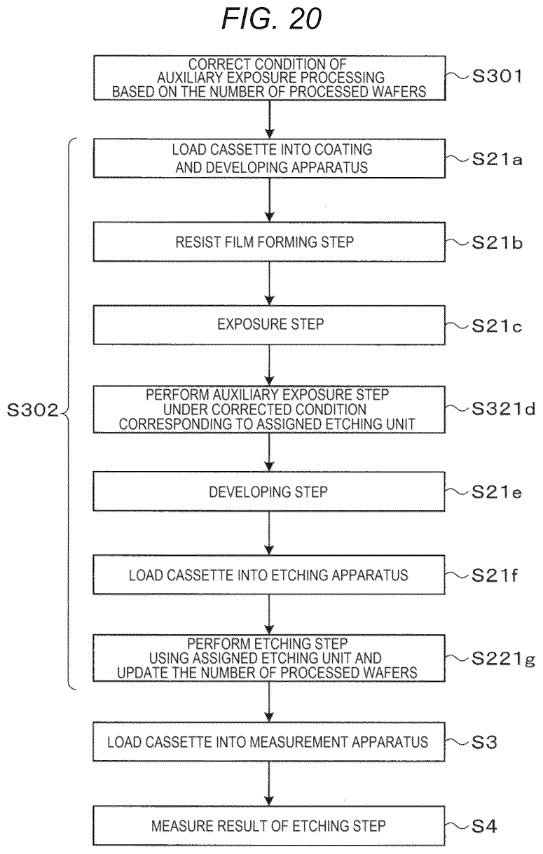

An example of the processing of the wafer W by the processing system according to the present embodiment will be described. FIG. 20 is a flowchart for showing an example of processing of the wafer W by a processing system according to the present embodiment.

### [Step S301]

In processing of the wafer W by the processing system according to the present embodiment, the in-plane distribution of the exposure amount in the auxiliary exposure processing is corrected based on the number of actually processed wafers processed by an etching unit, as shown in FIG. 20.

Specifically, the control device 6 calculates correction data for the in-plane distribution of the exposure amount in the auxiliary exposure processing for each unit ID as follows.

That is, first, the control device 6 extracts the number of actually processed wafers corresponding to the unit ID. Next, the control device 6 acquires a predicted result of the etching step when a series of steps are performed using an etching unit with the unit ID, specifically, a predicted in-plane distribution of an error with respect to a target value of a dimension of a pattern of an etching target layer, based on the extracted number of actually processed wafers. The control device 6 calculates correction data for the in-plane distribution of the exposure amount in the auxiliary exposure processing, based on the acquired predicted in-plane distribution, in the same manner as the method described in step S12.

The calculated correction data is stored in the correction data storage unit 6b for each etching unit, that is, for each unit ID.

The control device 6 acquires the predicted in-plane distribution of the error based on the number of actually processed wafers described above using, for example, the following data. In other words, the data is data showing a correspondence between the number of actually processed wafers and the predicted in-plane distribution of the error. The data is acquired in advance and stored in the storage unit (not shown) of the control device 6. The data may be different for each etching unit, or maybe the same between etching units. When the data is different for each etching unit, the auxiliary exposure can be more appropriately performed.

Step S301 is performed again as necessary when the number of actually processed wafers processed by the etching unit is updated in step S221d.

### [Step S302]

Thereafter, the control device 6 executes control such that a series of steps are performed for each wafer W under corrected conditions corresponding to an etching unit scheduled to be used in a subsequent etching step.

Specifically, steps S21a, S21b, and S21c described above are performed, a resist film is formed on the wafer W, and main exposure is performed.

### Step S321d

Next, the control device 6 executes control so as to perform an auxiliary exposure step under a corrected condition corresponding to an etching unit scheduled to be used in a subsequent etching step.

In step S321d, corrected exposure data corresponding to the etching unit assigned to the wafer W that is the processing target is used.

Specifically, for example, the control device 6 refers to the corresponding unit ID storage unit 6c, extracts a unit ID corresponding to a wafer ID assigned to the wafer W that is the processing target, and further refers to the correction data storage unit 6b, extracts correction data corresponding to the extracted unit ID, and sends the correction data to the controller U of the coating and developing apparatus 2. Then, before the auxiliary exposure in step S121d, the controller U of the coating and developing apparatus 2 generates corrected exposure data corresponding to the etching unit assigned to the wafer W that is the processing target, based on the correction data received from the control device 6 and the uncorrected exposure data stored in advance in a storage unit (not shown). The corrected exposure data is used for auxiliary exposure.

Subsequently, step S21e described above is performed.

Steps S21b, S21c, S321d, and S21e described above are performed for, for example, all of the wafers W in the cassette C.

Next, similar to step S21f described above, the cassette C that accommodates the wafer W on which the resist pattern is formed is loaded into the cassette station 200 of the etching apparatus 3.

When the processing system according to the present embodiment includes the plurality of etching apparatuses 3, the cassette C is transferred to the cassette station 200 of the etching apparatus 3 having the etching unit assigned to the wafer W in the cassette C, under control of the control device 6.

Subsequently, step S221g described above is performed, the etching step is performed under a desired processing condition using a specific etching unit assigned to the wafer W, and information on the number of processed wafers of the specific etching unit assigned to the wafer W is updated.

In the present embodiment as well, the above-described steps S3 and S4 may be performed.

### Main Effect of Present Embodiment

According to the present embodiment as well, the in-plane distribution of the dimension of the resist pattern obtained through the auxiliary exposure processing after correction can be made to a distribution corresponding to the in-plane distribution of the etching mode (specifically, an etching rate or the like) in the etching unit scheduled to be used in the etching step. Therefore, by performing the etching step using the resist pattern obtained through auxiliary exposure processing after correction as a mask, the in-plane uniformity of the pattern of the etching target layer can be more appropriately improved. According to the present embodiment, a time required for correction of the auxiliary exposure processing can be shortened.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

1. A substrate processing method comprising:
(A) applying a resist liquid on a substrate to form a resist film,
(B) performing auxiliary exposure processing of irradiating the resist film with light having a desired wavelength, separately from exposure processing of transferring a pattern of a mask onto the resist film,
(C) supplying a developer to the resist film after the exposure processing and the auxiliary exposure processing to form a resist pattern,
(D) etching an etching target layer on the substrate using the resist pattern as the mask, and
(E) correcting an in-plane distribution of an exposure amount in the auxiliary exposure processing in (B), and performing the correction based on a result of (D) when (A) to (D) are performed under conditions before the correction.

2. The substrate processing method according to claim 1, wherein
(D) is performed using any one of etching units, and
the result of (D) used for the correction in (E) is a statistical value among the etching units.

3. The substrate processing method according to claim 1, wherein
(D) is performed using any one of etching units, and
the result of (D) used for the correction in (E) is a result obtained when (D) is performed using the etching unit scheduled to be used in subsequent (D).

4. The substrate processing method according to claim 1, wherein
(E) includes measuring a result of (D) when (A) to (D) are actually performed under the conditions before the correction, and the correction is performed based on a measurement result.

5. The substrate processing method according to claim 3, wherein
(E) includes measuring a result of (D) when (A) to (D) are actually performed under the conditions before the correction, and the correction is performed based on a measurement result.

6. The substrate processing method according to claim 5, wherein
in (E), the correction is performed based on the number of substrates on which (D) is actually performed using the etching unit scheduled to be used in (D) and the measurement result.

7. The substrate processing method according to claim 3, wherein
(E) includes acquiring a predicted result of (D) when (A) to (D) are performed under the conditions before the correction, based on the number of substrates on which (D) is actually performed using the etching unit scheduled to be used in (D), and the correction is performed based on the acquired result.

8. A computer-readable recording medium storing a program that operates on a computer of a control device that controls a substrate processing system to cause the substrate processing system to perform a substrate processing method of processing a substrate, wherein
the substrate processing method includes
(A) applying a resist liquid on the substrate to form a resist film,
(B) performing auxiliary exposure processing of irradiating the resist film with light having a desired wavelength, separately from exposure processing of transferring a pattern of a mask onto the resist film,
(C) supplying a developer to the resist film after the exposure processing and the auxiliary exposure processing to form a resist pattern,
(D) etching an etching target layer on the substrate using the resist pattern as the mask, and
(E) correcting an in-plane distribution of an exposure amount in the auxiliary exposure processing in (B), and performing the correction based on a result of (D) when (A) to (D) are performed under conditions before the correction.

9. A substrate processing system comprising:
a substrate processing apparatus including:
a resist coating applicator for applying a resist liquid on a substrate to form a resist film;
an auxiliary exposurer for performing auxiliary exposure processing of irradiating the resist film with light having a desired wavelength separately from exposure processing of transferring a pattern of a mask to the resist film; and
a developer for supplying a developer to the resist film to form a resist pattern,
an etching apparatus including an etcher for etching a substrate, and
circuitry configured to execute control to (a) form the resist film on the substrate by the resist coating applicator, (b) perform auxiliary exposure processing by the auxiliary exposurer, (c) form the resist pattern by the developer from the resist film after the exposure processing and the auxiliary exposure processing, (d) etch an etching target layer on the substrate by the etcher using the resist pattern as a mask, and (e) correct an in-plane distribution of an exposure amount in the auxiliary exposure processing in (b), and perform the correction based on a result of (d) when (a) to (d) are performed under conditions before the correction.

10. The substrate processing system according to claim 9, further comprising:
a plurality of the etchers, wherein
the result of (d) used for the correction in (e) is a statistical value among the etchers.

11. The substrate processing system according to claim 9, further comprising:
a plurality of the etcher, wherein
the result of (d) used for the correction in (e) is a result obtained when (d) is performed using the etcher scheduled to be used in subsequent (d).

12. The substrate processing system according to claim 9, further comprising:
a measurement apparatus for measuring a result of etching performed by the etcher, wherein
in (e), control, by the circuitry, is executed such that the measurement apparatus measures the result of (d) when (a) to (d) are actually performed under the conditions before the correction, and the correction is performed based on the measurement result.

13. The substrate processing system according to claim 11, further comprising:
a measurement apparatus for measuring a result of etching performed by the etcher, wherein
in (e), control is executed such that the measurement apparatus measures the result of (d) when (a) to (d) are actually performed under the conditions before the correction, and the correction is performed based on the measurement result.

14. The substrate processing system according to claim 13, wherein
in (e), the correction is performed based on the number of substrates on which (d) is actually performed using the etcher scheduled to be used in subsequent (d) and the measurement result.

15. The substrate processing system according to claim 11, wherein
(e) includes acquiring a predicted result of (d) when (a) to (d) are performed under the conditions before the correction, based on the number of substrates on which (d) is actually performed using the etcher scheduled to be used in subsequent (d), and the correction is performed based on the acquired result.

16. A substrate processing apparatus comprising:
a resist coating applicator for applying a resist liquid on a substrate to form a resist film,
an auxiliary exposurer for performing auxiliary exposure processing of irradiating the resist film with light having a desired wavelength separately from exposure processing of transferring a pattern of a mask to the resist film,
a developer for supplying a developer to the resist film to form a resist pattern, and
circuitry configured to execute control to (a) form the resist film on the substrate by the resist coating applicator, (b) perform auxiliary exposure processing by the auxiliary exposurer, (c) form the resist pattern by the developer from the resist film after the exposure processing and the auxiliary exposure processing, and (e) correct an in-plane distribution of an exposure amount in the auxiliary exposure processing in (b), and perform the correction based on results of (a) to (c) and (d) of etching an etching target layer on the substrate by the etcher using the resist pattern as a mask after (c), under conditions before the correction.

17. The substrate processing apparatus according to claim 16, wherein
the etcher used in (d) is any one of etchers, and
the result of (d) used for the correction in (e) is a result obtained when (d) is performed using the etcher scheduled to be used in subsequent (d).

18. The substrate processing apparatus according to claim 17, wherein
(e) includes acquiring a result obtained by measuring the result of (d) when (a) to (d) are actually performed under the conditions before the correction, and the correction is performed based on the acquired result.

19. The substrate processing apparatus according to claim 18, wherein
in (e), the correction is performed based on the number of substrates on which (d) is actually performed using the etcher scheduled to be used in (d) and the acquired result.

20. The substrate processing apparatus according to claim 17, wherein
(e) includes acquiring a predicted result of (d) when (a) to (d) are performed under the conditions before the correction, based on the number of substrates on which (d) is actually performed using the etcher scheduled to be used in (d), and the correction is performed based on the acquired result.
